(19) United States
(12) Patent Application Publication
(10) Pub. No.: US 2005/0052342 A1
(43) Pub. Date: Mar. 10, 2005

(54) Dual display device

(75) Inventors: Jie-Farn Wu, Miaoli (TW); Tien-Rong Lu, Tainan City (TW); Tung-Sheng Cheng, Hsinchu (TW); Pei-Chuan Yeh, Hsinchu City (TW)

Correspondence Address: BIRCH STEWART KOLASCH & BIRCH, PO BOX 747, FALLS CHURCH, VA, 22040-0747, US

(73) Assignee: RITDISPLAY CORPORATION, Hsin Chu Industrial Park (TW)

(21) Appl. No.: 10/902,107

(22) Filed: Jul. 30, 2004

(30) Foreign Application Priority Data
Jul. 31, 2003 (TW) 092121064
Jul. 31, 2003 (TW) 092121065

(51) Int. Cl. G09G 5/00

(52) U.S. Cl. 345/4

(57) ABSTRACT

A dual display device comprises a first display panel, a second display panel and an adhesive. The first display panel comprises, in sequence, a first transparent substrate, a first electrode, a first organic functional layer and a second electrode. The second display panel comprises, in sequence, a second transparent substrate, a third electrode, a second organic functional layer and a fourth electrode. The second electrode and the fourth electrode are disposed opposite to each other. The adhesive seals the first transparent substrate and the second transparent substrate.

### BACKGROUND OF THE INVENTION

1. Field of Invention

The invention relates to a display device and, in particular, to a dual display device.

2. Related Art

The present electronic devices have become more compact and lightweight, so the flat-panel displays thereof accordingly become more important. In addition, the electronic devices comprise various applications, wherein the electronic devices with dual display devices for displaying plentiful information are one of the major features of the new generation electronic products. For example, the mobile phone may include a dual display device, which can be used as a main-display panel and a sub-display panel, respectively.

The conventional dual display device is manufactured by attaching two single display panels, such as LCD panels or organic electroluminescent (OEL) panels. With reference to FIG. 1, a conventional dual display device 3 includes a first display panel 31 and a second display panel 32. Wherein the first display panel 31 includes a transparent substrate 311, a first electrode 312, a light-emitting area 313, a second electrode 314, and a cover plate 315. The light-emitting area 313 is sandwiched between the first electrode 312 and the second electrode 314. The first electrode 312 is disposed on the transparent substrate 311, and the cover plate 315 is attached to the transparent substrate 311 with an adhesive. In addition, the second display panel 32 includes a transparent substrate 321, a third electrode 322, a light-emitting area 323, a fourth electrode 324, and a cover plate 325. The light-emitting area 323 is sandwiched between the first electrode 322 and the second electrode 324. The first electrode 322 is disposed on the transparent substrate 321, and the cover plate 325 is attached to the transparent substrate 321 with an adhesive. In this case, the cover plate 315 of the first display panel 31 is opposite to and attached to the cover plate 325 of the second display panel 32 so as to form the conventional dual display device 3.

However, since the conventional dual display device includes two cover plates 315 and 325 and two transparent substrates 311 and 321, the whole dual display device has a larger size, thickness, and weight, which can not match the trend towards the electronic device with more compact and lightweight.

It is therefore a subjective of the invention to provide a dual display device, which can solve the above-mentioned problems.

### SUMMARY OF THE INVENTION

In view of the foregoing, the invention is to provide a compact and lightweight dual display device.

To achieve the above, a dual display device of the invention comprises a first display panel, a second display panel and an adhesive. In the invention, the first display panel sequentially comprises a first transparent substrate, a first electrode, a first organic functional layer and a second electrode. The second display panel sequentially comprises a second transparent substrate, a third electrode, a second organic functional layer and a fourth electrode. The second electrode and the fourth electrode are disposed opposite to each other. The adhesive seals the first transparent substrate and the second transparent substrate.

To achieve the above, a dual display device of the invention comprises a first display panel, a second display panel, an adhesive, and a drying unit. In the invention, the first display panel sequentially comprises a first transparent substrate, a first electrode, a first organic functional layer and a second electrode. The second display panel sequentially comprises a second transparent substrate, a third electrode, a second organic functional layer and a fourth electrode. The second electrode and the fourth electrode are disposed opposite to each other. The adhesive seals the first transparent substrate and the second transparent substrate. The drying unit is disposed between the first transparent substrate and the second transparent substrate.

As mentioned above, the dual display device utilizes the adhesive to seal the two display panels. Comparing with the prior art, the dual display device of the present invention saves two cover plates and cover plates are not necessary to be used in the present invention any more. Thus, the thickness of the whole device is more compact and more lightweight, and the cost of the dual display device is decreased. In addition, the adhesive of the invention is doped with solids, which can increase the diffusion path length and diffusion time of the external moisture and oxygen. Therefore, the lifetime and stability of the device are improved, and the damages of the organic electroluminescent elements (the organic functional layers) caused by package pressing can be prevented. Moreover, the solids can control the gap between two transparent substrates, and further provide a space for accommodating the drying unit. The drying unit can desiccate the moisture inside the device, which can prolong the lifetime of the device and increase the operation reliability. The two display panels of the dual display device of the invention can individually show image information, so as to enhance the display information capacity of the whole device. In summary, the dual display device of the invention is not only compact and lightweight, but also has a lower manufacturing cost. Furthermore, the dual display device of the invention has a longer lifetime, a better stability, and a simple information arrangement, so that it is suitable for mass production.

### BRIEF DESCRIPTION OF THE DRAWINGS

The invention will become more fully understood from the detailed description given hereinbelow illustration only, and thus is not limitative of the present invention, and wherein:

FIG. 1 is a schematic view showing the conventional dual display device;

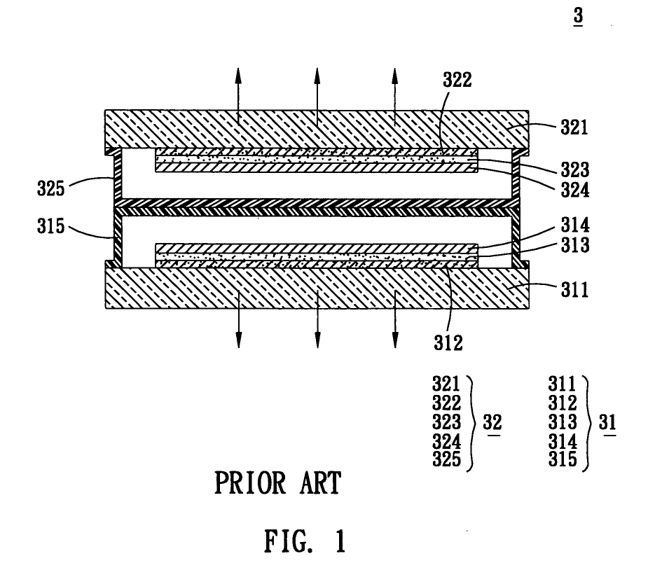

FIG. 2A is a schematic view showing a dual display device according to a first embodiment of the invention;

FIG. 2B is a sectional schematic view along the line A-A shown in FIG. 2A;

FIG. 3 is a schematic view showing another dual display device according to the first embodiment of the invention;

FIG. 4 is a schematic view showing an additional dual display device according to the first embodiment of the invention;

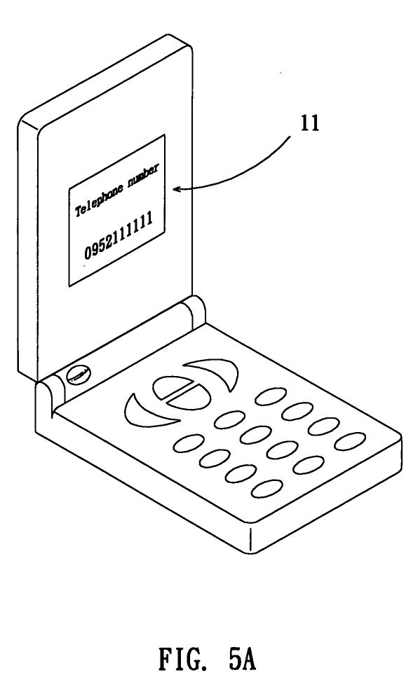

FIGS. 5A and 5B are schematic views showing an application of the dual display device shown in FIG. 2A; and

FIG. 6 is a schematic view showing a dual display device according to a second embodiment of the invention.

### DETAILED DESCRIPTION OF THE INVENTION

The present invention will be apparent from the following detailed description, which proceeds with reference to the accompanying drawings, wherein the same references relate to the same elements.

### FIRST EMBODIMENT

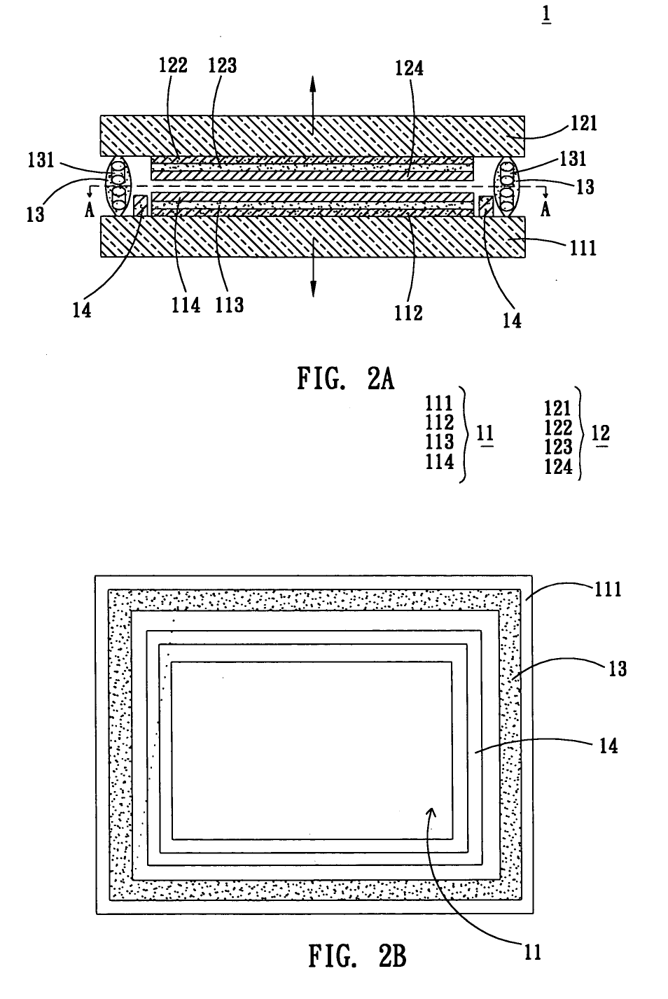

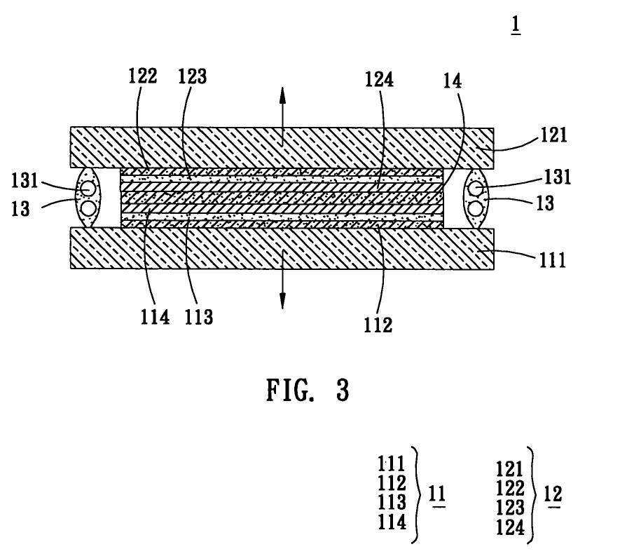

As shown in FIG. 2A, a dual display device 1 according to a first embodiment of the invention comprises a first display panel 11, a second display panel 12 and an adhesive 13. In the embodiment, the first display panel 11 comprises, in sequence, a first transparent substrate 111, a first electrode 112, a first organic functional layer 113 and a second electrode 114. The second display panel 12 comprises, in sequence, a second transparent substrate 121, a third electrode 122, a second organic functional layer 123, and a fourth electrode 124. The second electrode 114 and the fourth electrode 124 are disposed opposite to each other. The adhesive 13 seals the first transparent substrate 111 and the second transparent substrate 121.

In the present embodiment, the first transparent substrate 111 can be a flexible or a rigid substrate. The first transparent substrate 111 can also be a plastic or glass substrate. In particular, the flexible substrate or plastic substrate can be made of polycarbonate (PC), polyester (PET), cyclic olefin copolymer (COC), or metallocene-based cyclic olefin copolymer (mCOC).

The first electrode 112 is disposed on the first transparent substrate 111 by a sputtering method or an ion plating method. The first electrode 112 is usually used as an anode and made of a transparent conductive metal oxide, such as indium-tin oxide (ITO), aluminum-zinc oxide (AZO), or indium-zinc oxide (IZO).

The first organic functional layer 113 usually comprises a hole-injecting layer, a hole-transporting layer, a light-emitting layer, an electron-transporting layer and an electron-injecting layer (not shown). The first organic functional layer 113 can be formed on the first electrode 112 by utilizing evaporation, spin coating, ink jet printing, or printing. In addition, the light emitted from the first organic functional layer 113 can be blue, green, red, white, other monochromatic light, or a colorful light as a combination of monochromatic lights.

Referring to FIG. 2A again, the second electrode 114 is disposed on the first organic functional layer 113. Herein, the second electrode 114 can be formed on the first organic functional layer 113 by way of evaporation or sputtering. The material of the second electrode 114 can be aluminum, calcium, magnesium, indium, zinc, manganese, silver, gold, and magnesium alloy. The magnesium alloy can be, for example, Mg:Ag alloy, Mg:In alloy, Mg:Sn alloy, Mg:Sb alloy and Mg:Te alloy.

In this case, the features and functions of the second transparent substrate 121, the third electrode 122, the second organic functional layer 123, and the fourth electrode 124 are the same to the first transparent substrate 111, the first electrode 112, the first organic functional layer 113, and the second electrode 114 described previously, so the detailed descriptions are omitted here for concise purpose.

With reference to FIG. 2A, the adhesive 13 is doped with a plurality of solids 131, and is used to seal the first transparent substrate 111 and the second transparent substrate 121. In the embodiment, the adhesive 13 is a photo-cured adhesive, such as the UV glue. Of course, the adhesive 13 can also be a thermal-cured adhesive.

In the present embodiment, the solids 131 can be glass fibers or glass beads, and the solids 131 can be spherical and/or cylindrical. Of course, the adhesive 13 can be also doped with a free radical catcher and/or a drying material such as barium oxide (BaO).

In the current embodiment, the solids 131 doped in the adhesive 13 can increase the diffusion path length and diffusion time of the external moisture and oxygen. Therefore, the lifetime and stability of the device are improved. In addition, the solids 131 of the adhesive 13 can control the distance between the first transparent substrate 111 and the second transparent substrate 121, so that the damages of the organic electroluminescent elements (including the first electrode 112, the first organic functional layer 113, the second electrode 114, the third electrode 122, the second organic functional layer 123, and the fourth electrode 124) caused by package pressing can be prevented. Furthermore, an accommodating space can be formed.

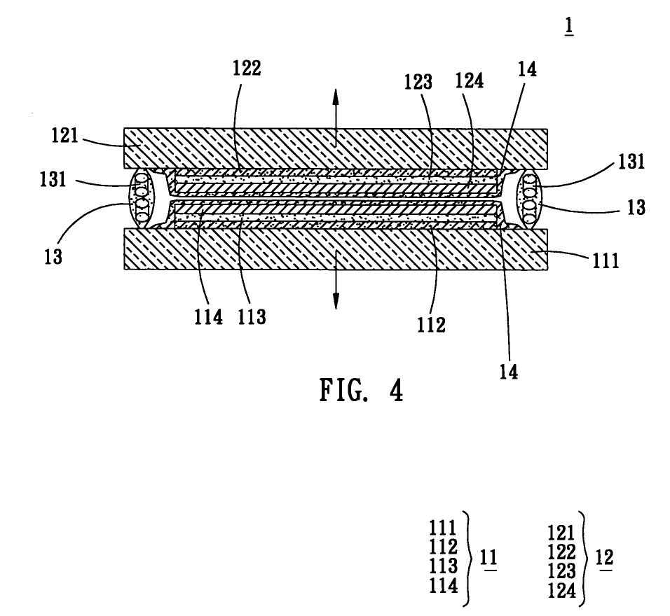

With reference to FIGS. 2A and 2B, the dual display device 1 of the embodiment may further comprise a drying unit 14, which is disposed between the first transparent substrate 111 and the second transparent substrate 121 (the accommodating space). Herein, the drying unit 14 can be disposed on the second electrode 114 and/or the fourth electrode 124 directly (as shown in FIG. 3). Of course, a buffer layer (not shown) can be provided between the drying unit 14 and the second electrode 114 or between the drying unit 14 and the fourth electrode 124. The buffer layer is, for example, UV glue or a thermal-cured adhesive. Moreover, the drying unit 14 may be a tape-shaped for applying on the first display panel 11 and/or on the second display panel 12.

Since the first organic functional layer 113 and the second organic functional layer 123 (the organic electroluminescent elements) are very sensitive to moisture and oxygen, dark spots may be happened when the elements contact with air. Thus, the drying unit 14 is used to prevent the first organic functional layer 113 and the second organic functional layer 123 from being damaged by moisture and oxygen. In this case, the drying unit 14 may comprise desiccants, such as BaO, for desiccating the water contained in the dual display device 1 after they are encapsulated. This can efficiently prolong the lifetime of the dual display device.

In addition, the dual display device 1 of the embodiment may further comprise a driving circuit (not shown), which is a passive driving circuit or an active driving circuit. The driving circuit couples to the first display panel 11, the second display panel 12, and a power (not shown).

In the embodiment, the first display panel 11 and the second display panel 12 are individually driven. In other words, the applied voltages for the first display panel 11 and the second display panel 12 may be different from one another according to practical demands. Herein, the second display panel 12 can be used as a sub-display panel, which cooperates with the first display panel 11 to increase the convenient of users. In this case, the first display panel 11 and the second display panel 12 may respectively show films, picture, or numerals according to the demands. Of course, the first display panel 11 and the second display panel 12 can be driven at the same time.

In addition, the dual display device 1 of the embodiment further comprises an image transform module (not shown), which controls the image orientations of the first display panel 11 and the second display panel 12. In details, when the displayed image data of the second display panel 12 is transmitted from the first display panel 11, the image transform module may adjust the image orientation of the second display panel 12 according to the image data from the first display panel 11 based on the operation situation for facilitating users to view the image information. For example, the image data may be turned to the orientation directly facing the user.

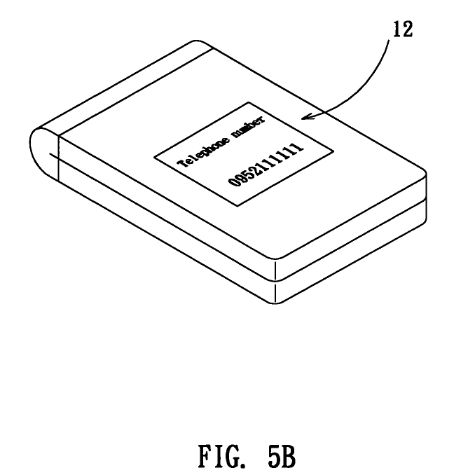

Hereinafter, an example is shown, wherein the dual display device is embodied in a mobile phone with reference to FIGS. 5A and 5B. Wherein, FIGS. 5A and 5B are schematic views showing an application of the dual display device shown in FIG. 2A.

As shown in FIG. 5A, when a user opens the mobile phone, the first display panel 11 displays the telephone number of the caller and other relative information. In addition, as shown in FIG. 5B, when the user closes the mobile phone, the second display panel 12 displays different information, such as the local time, from that displayed on the first display panel 11. Of course, the second display panel 12 may display the same information as that displayed on the first display panel 11. In this case, the image information is firstly transmitted to the second display panel 12. The image transform module detects the operation situation and then transforms the image of the second display panel 12 to the orientation directly facing the user's eyes according to the detected results.

### SECOND EMBODIMENT

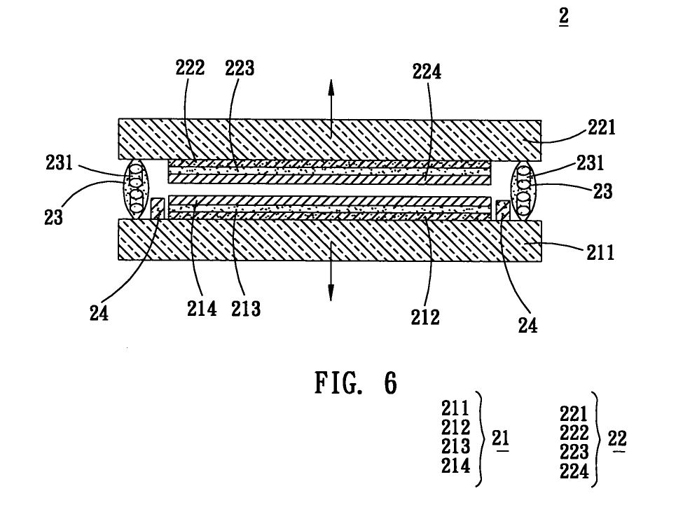

Referring to FIG. 6, a dual display device 2 according to the second embodiment of the invention comprises a first display panel 21, a second display panel 22, an adhesive 23 and a drying unit 24. In the invention, the first display panel 21 comprises, in sequence, a first transparent substrate 211, a first electrode 212, a first organic functional layer 213 and a second electrode 214. The second display panel 22 comprises, in sequence, a second transparent substrate 221, a third electrode 222, a second organic functional layer 223 and a fourth electrode 224. The second electrode 214 and the fourth electrode 224 are disposed opposite to each other. The adhesive 23 seals the first transparent substrate 211 and the second transparent substrate 221. The drying unit 24 is disposed between the first transparent substrate 211 and the second transparent substrate 221.

In the present embodiment, the adhesive 23 may be doped with a plurality of solids 231. In addition, the adhesive 23 may be also doped with a free radical catcher and/or a drying material.

In this embodiment, the features and functions of the first display panel 21, the first transparent substrate 211, the first electrode 212, the first organic functional layer 213, the second electrode 214, the second display panel 22, the second transparent substrate 221, the third electrode 222, the second organic functional layer 223, the fourth electrode 224, the adhesive 23, the solids 231 and the drying unit 24 are the same to those in the first embodiment, so the detailed descriptions of the elements are omitted here for concise purpose.

In the embodiment, the dual display device 2 may further comprise an image transform module (not shown) and a driving circuit (not shown). Those elements of the second embodiment are the same as those described in the first embodiment, so the detailed descriptions are omitted here for concise purpose.

As mentioned above, the dual display device of the invention utilizes the adhesive to seal the two display panels. Comparing with the prior art, the dual display device of the present invention saves two cover plates and cover plates are not necessary to be used in the dual display device any more. Thus, the thickness of the whole device is more compact and more lightweight, and the cost of the dual display device is decreased. In addition, the adhesive of the invention is doped with solids, which can increase the diffusion path length and diffusion time of the external moisture and oxygen. Therefore, the lifetime and stability of the device are improved, and the damages of the organic electroluminescent elements (the organic functional layers) caused by package pressing can be prevented. Moreover, the solids can control the gap between two transparent substrates, and further provide a space for accommodating the drying unit. The drying unit can desiccate the moisture inside the device, which can prolong the lifetime of the device and increase the operation reliability. The two display panels of the dual display device of the invention can individually show image information, so as to enhance the display information capacity of the whole device. In summary, the dual display device of the invention is not only compact and lightweight, but also has a lower manufacturing cost. Furthermore, the dual display device of the invention has a longer lifetime, a better stability, and a simple information arrangement, so that it is suitable for mass production.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A dual display device, comprising:
a first display panel, which sequentially comprises a first transparent substrate, a first electrode, a first organic functional layer, and a second electrode;
a second display panel, which sequentially comprises a second transparent substrate, a third electrode, a second organic functional layer, and a fourth electrode, wherein the second electrode and the fourth electrode are disposed opposite to each other; and
an adhesive, which seals the first transparent substrate and the second transparent substrate.

2. The dual display device of claim 1, wherein the first transparent substrate and the second transparent substrate are at least one selected from the group consisting of a rigid substrate, a flexible substrate, a glass substrate and a plastic substrate.

3. The dual display device of claim 1, wherein the first electrode and the third electrode comprise conductive metal oxide.

4. The dual display device of claim 3, wherein the conductive metal oxide is at least one selected from the group consisting of indium-tin oxide (ITO), aluminum-zinc oxide (AZO) and indium-zinc oxide (IZO).

5. The dual display device of claim 1, wherein the second electrode and fourth electrode are made of at least one material selected from the group consisting of aluminum, calcium, magnesium, indium, zinc, manganese, silver, gold and magnesium alloy.

6. The dual display device of claim 5, wherein the magnesium alloy includes but not limited to Mg:Ag, Mg:In, Mg:Sn, Mg:Sb and Mg:Te.

7. The dual display device of claim 1, wherein the adhesive is a photo-cured adhesive or a thermal-cured adhesive.

8. The dual display device of claim 1, wherein the adhesive is doped with a plurality of solids.

9. The dual display device of claim 8, wherein the solids are glass fibers and/or glass beads.

10. The dual display device of claim 8, wherein the solids are spherical and/or cylindrical.

11. The dual display device of claim 1, wherein the adhesive is doped with a drying material and/or a free radical catcher.

12. The dual display device of claim 1, further comprising:
a drying unit, which is disposed between the first transparent substrate and the second transparent substrate.

13. The dual display device of claim 12, wherein the drying unit is disposed between the second electrode and the fourth electrode.

14. The dual display device of claim 13, further comprising:
a buffer layer, which is disposed between the drying unit and the second electrode and/or between the drying unit and the fourth electrode.

15. The dual display device of claim 12, wherein the drying unit is disposed on the first display panel and/or the second display panel.

16. The dual display device of claim 1, further comprising:
an image transform module, which controls the image orientation of the first display panel or the second display panel.

17. A dual display device, comprising:
a first display panel, which sequentially comprises a first transparent substrate, a first electrode, a first organic functional layer, and a second electrode;
a second display panel, which sequentially comprises a second transparent substrate, a third electrode, a second organic functional layer, and a fourth electrode, wherein the second electrode and the fourth electrode are disposed opposite to each other;
an adhesive, which seals the first transparent substrate and the second transparent substrate; and
a drying unit, which is disposed between the first transparent substrate and the second transparent substrate.

18. The dual display device of claim 17, wherein the adhesive is doped with a plurality of solids.

19. The dual display device of claim 18, wherein the solids are glass fibers and/or glass beads.

20. The dual display device of claim 17, wherein the adhesive is doped with a drying material and/or a free radical catcher.
